(19) United States
(12) Patent Application Publication
(10) Pub. No.: US 2020/0227573 A1
(43) Pub. Date: Jul. 16, 2020

(54) OPTOELECTRONIC DEVICE

(71) Applicant: Commissariat A L'Energies Atomique et aux Energies Alternatives, Paris (FR)

(72) Inventors: Cedric DUCROS, Grenoble Cedex (FR); Nicolas Dunoyer, Grenoble Cedex (FR); Emmanuel Ollier, Grenoble Cedex (FR); Helga Szambolics, Grenoble Cedex (FR)

(73) Assignee: Commissariat A L'Energies Atomique et aux Energies Alternatives, Paris (FR)

(21) Appl. No.: 16/703,998

(22) Filed: Jan. 30, 2020

(30) Foreign Application Priority Data
Dec. 10, 2018 (FR) 18 72611

(51) Int. Cl. H01L 31/0236; H01L 31/0224; H01L 31/0216; H01L 31/042; G02B 1/11; G02B 5/02

(52) U.S. Cl. CPC H01L 31/02366; H01L 31/02363; H01L 31/022466; G02B 5/0221; H01L 31/042; G02B 1/11; H01L 31/0216

(57) ABSTRACT

The invention concerns an optronic device (1), comprising:
a glass substrate (2) having opposed and textured first and second surfaces (21, 22);
an electrically conductive material (3) continuous and formed on the second surface (22) of the glass substrate;
a photovoltaic sensor thin film (4) formed on the electrically conductive material (3);
the texturing of the first surface (21) of the glass substrate is configured to have a weighted optical reflection in the visible spectrum of less than 3%;
the texturing of the second surface (22) of the glass substrate is configured to diffuse the light transmitted from the substrate to the transparent electrode (3).

The invention relates to photovoltaic transducers, in particular such transducers with a transparent substrate and electrode.

An optronic device conventionally comprises a transparent substrate, a photovoltaic sensor to absorb light and convert it into electricity, and a transparent electrode to collect the electricity generated, the electrode being disposed between the substrate and the photovoltaic sensor.

A transparent substrate is generally made of glass, such as borosilicate or soda-lime glass. A transparent electrode is frequently made of transparent conductive oxide such as doped indium oxide, doped zinc oxide, or doped tin oxide.

Refractive index transitions at the interfaces inside the transducer cause light reflections. Such light reflections reduce the conversion efficiency of the optronic device, with a reduced amount of light reaching the photovoltaic sensor. Light reflections can also be harmful to the environment in some applications, generating glare or making the device optronic.

A known solution to reduce transmission at the interface between air and glass substrate is to deposit multiple anti-reflective layers with refractive indices lower than that of the glass substrate, these indices decreasing as they are further away from the substrate. Such anti-reflective coatings have a very variable efficiency depending on the angle of incidence of the light in relation to the glass substrate, or even very variable depending on the wavelength of this light. Moreover, such layers are not necessarily suitable for application between the substrate and the electrode.

Another known solution is to texture an interface of the optronic device, for example the interface with the air of the glass substrate. Such a textured interface provides an intermediate refractive index at the interface, which reduces reflection. Such an interface has a lower sensitivity to the angle of incidence of light compared to the glass substrate.

A process for texturing one surface of the glass forming an air/glass interface is described in the document ‘Optimal Moth Eye Nanostructure Array on Transparent Glass Towards Broadband Antireflection’, published by Seungmuk Ji et al, in the journal ACS Applied Material Interfaces, in 2013, 5, pages 10731-10737. According to this process, the glass is masked according to a pattern and then partially etched according to this pattern in order to obtain a regular texture.

The document ‘Antireflective grassy surface on glass substrates with self-masked dry etching’, published by M. Song et al, in Nanoscale Research Letters 2013, 8:505, describes a process for texturing one surface of the glass forming an air/glass interface. This process is based on dry etching of the reactive ion etching type in a CF₄/O₂ mixture and simplifies the fabrication process by avoiding the use of masks.

The document ‘SF6/Ar Plasma textured periodic glass surface morphologies with high transmittance and haze ratio of ITO:ZR films for amorphous silicon thin film solar cells’ by Hussain et al, published in Vacuum 117 pages 91 to 97, describes a process for texturing a glass panel to obtain a diffusion by TCO deposited on the formed texture. This document proposes a dry etching process through an etching mask. Such a process is relatively complex to implement. In addition, the process used tends to degrade the optical transmission at the interface with the electrode relative to a smooth substrate. This can affect the conversion efficiency of the optronic device, especially when the photovoltaic sensor is of the thin-film type.

Thus, there is no known solution that achieves both an effective anti-reflection effect at the air/glass interface and a significant increase in the conversion efficiency of the optronic device.

The invention aims to solve one or more of these disadvantages. The invention thus concerns an optronic device, as defined in the accompanying claims.

The skilled person will understand that each of the features of a dependent claim or of the description can be combined independently with the features of an independent claim, without constituting an intermediate generalization.

The invention also concerns a process for fabricating an optronic device, as defined in the accompanying claims.

Other features and advantages of the invention will emerge clearly from the description provided below, by way of indication and without limitation, with reference to the accompanying drawings, in which:

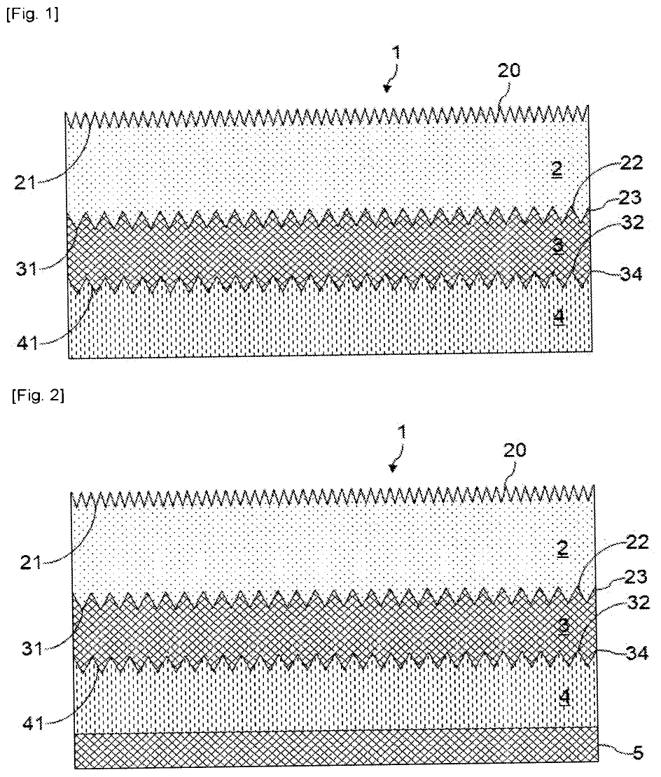

FIG. 1 is a schematic cross-sectional view of an exemplary optronic device according to an embodiment of the invention;

FIG. 2 is a schematic cross-sectional view of an exemplary optronic device according to another embodiment of the invention;

FIG. 3,

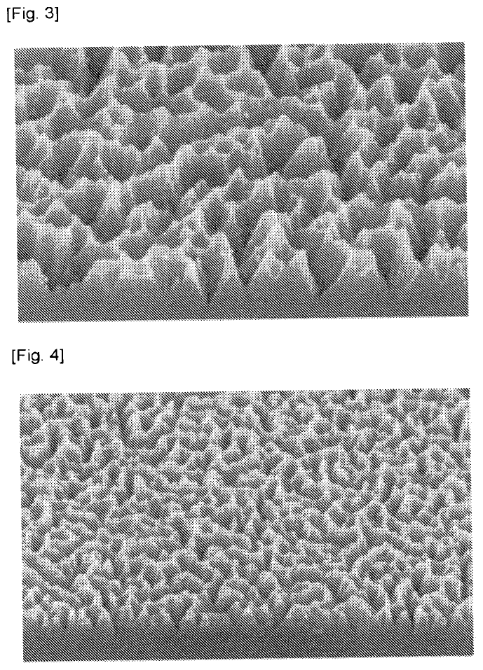

FIG. 4 and

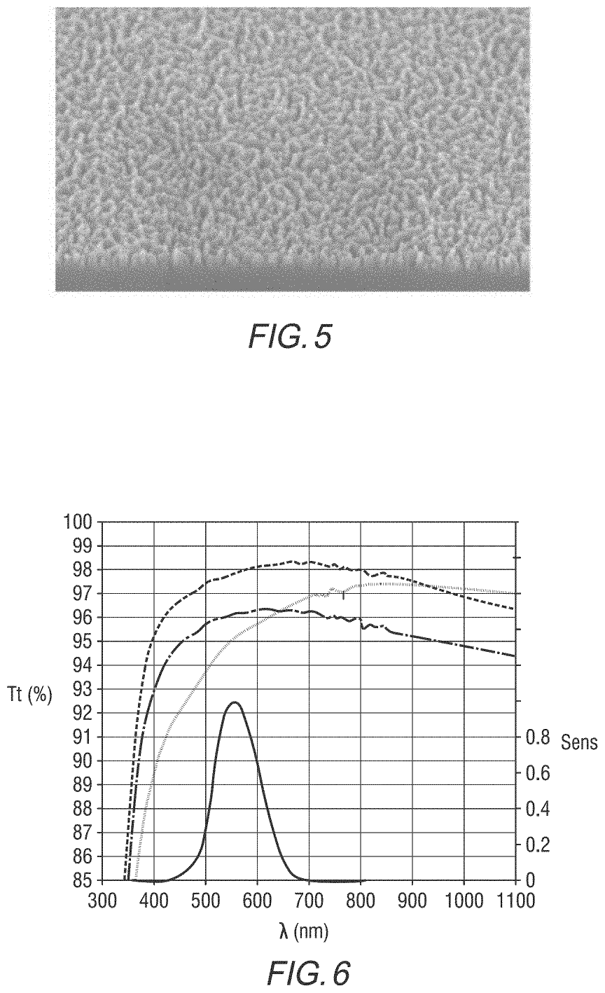

FIG. 5 are scanning electron microscope views of textured glass surfaces using different fabrication processes;

FIG. 6,

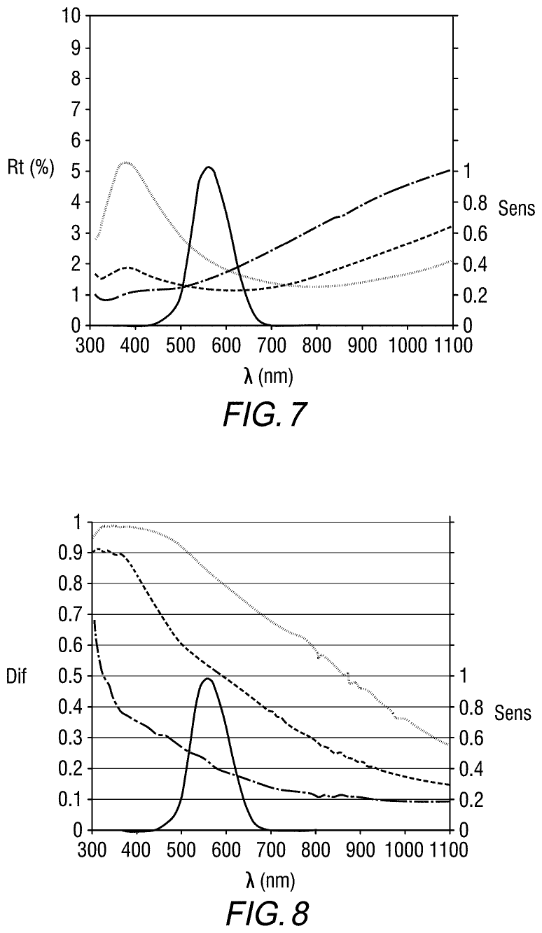

FIG. 7 and

FIG. 8 are diagrams illustrating different optical parameters of the textured glass surfaces shown in FIGS. 3 to 5;

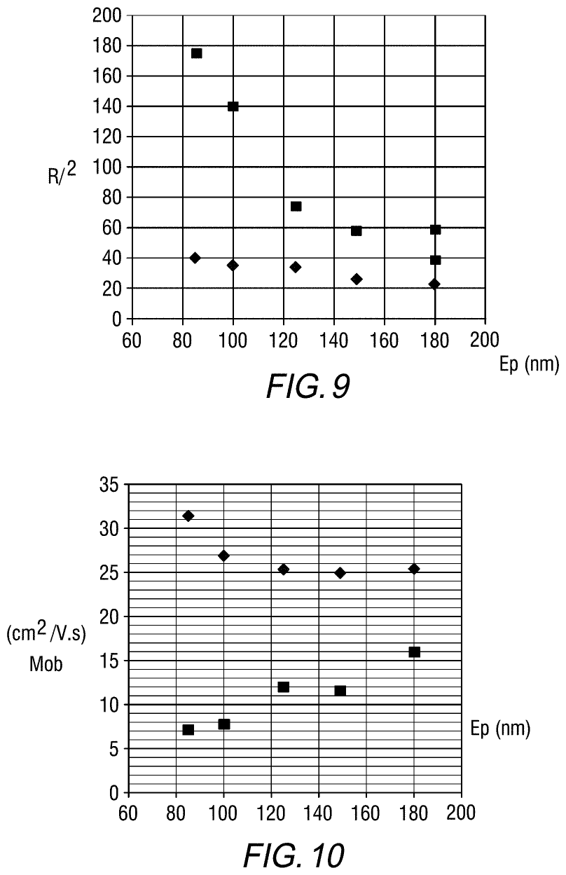

FIG. 9 is a diagram comparing the influence of the thickness of an electrically conductive material on its resistance, for an optronic device according to the invention and an optronic device according to the state of the art;

FIG. 10 is a diagram comparing the influence of the thickness of an electrically conductive material on its electron mobility, for an optronic device according to the invention and an optronic device according to the state of the art;

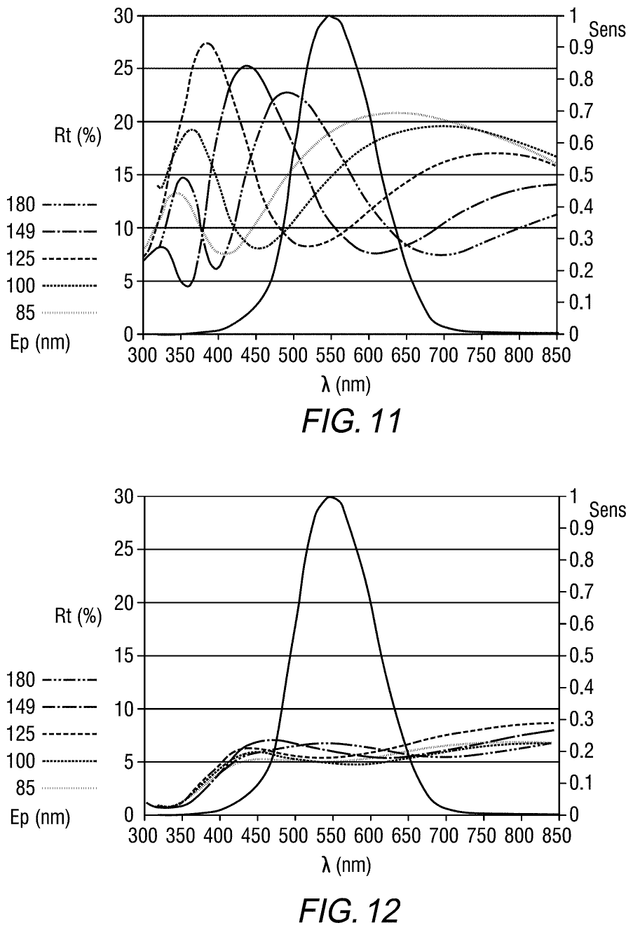

FIG. 11 is a diagram of the reflection spectra on electrically conductive material deposited on a substrate of the state of the art, as a function of the thickness of this electrically conductive material;

FIG. 12 is diagram of optical reflection spectra on an electrically conductive material deposited on a substrate for an optronic device according to the invention, as a function of the thickness of this electrically conductive material;

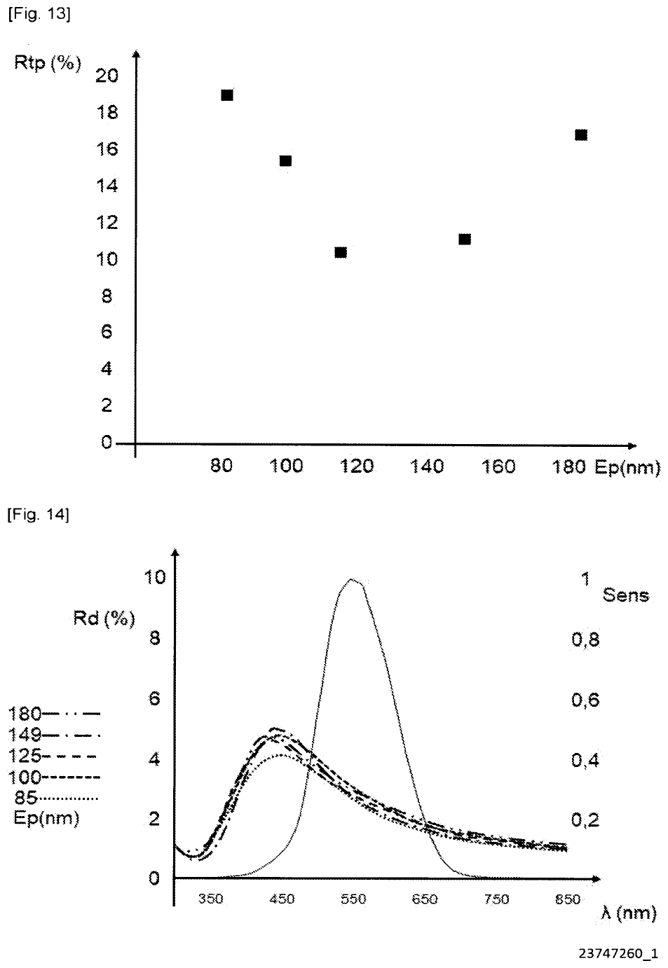

FIG. 13 is diagram of optical reflection spectra on an electrically conductive material deposited on a substrate for an optronic device according to the invention, as a function of the thickness of this electrically conductive material, with a weighting by human spectral sensitivity;

FIG. 14 is a diagram of diffuse optical reflection for different thicknesses of an electrically conductive material deposited on a textured substrate, for an optronic device according to the invention, as a function of wavelength.

A textured surface is defined as a surface with a roughness or relief relative to a smooth geometric shape.

FIG. 1 is a schematic cross-sectional view of an exemplary optronic device 1 according to an embodiment of the invention. The photovoltaic sensor 1 comprises a glass substrate 2, an electrically conductive material or transparent electrode 3 and a photovoltaic sensor 4. The transparent electrode 3 is positioned in contact between the glass substrate 2 and the photovoltaic sensor 4.

The substrate 2 is for example made of borosilicate glass or soda-lime glass. The glass substrate 2 has an outer surface 21 in contact with air at an interface 20, and an inner surface 22 in contact with the electrode 3 at an interface 23. The surfaces 21 and 22 are opposite and textured.

The transparent electrode 3 is continuous, in order to be able to collect and conduct the electrical charges generated by photon capture by the photovoltaic sensor 4. The electrode 3 is for example made of a conductive oxide such as doped zinc oxide, doped tin oxide, or doped indium oxide. The transparent electrode can also be made of an alloy of these materials, for example ITZO. The transparent electrode 3 has a surface 31 in contact with the surface 22 and of complementary shape. The transparent electrode 3 also has a surface 32, opposite to the surface 31.

The photovoltaic sensor 4 is a thin-film type, for reasons of compactness. A photovoltaic sensor 4 will typically be considered as a thin film if it has a thickness of less than 10 μm. Due to its thinness, the photovoltaic sensor 4 has the potential to convert light into relatively low electrical charges. Light transmission through the substrate 2 and the electrode 3 is therefore particularly important to increase the conversion efficiency of the photovoltaic sensor 4. The photovoltaic sensor 4 can also be of the semi-transparent thin film type, improving the conversion efficiency from light to electrical charges even further. The photovoltaic sensor 4 can have a composition known per se, for example can comprise a hydrogenated amorphous silicon (a-Si:H) thin film.

FIG. 2 is a schematic cross-sectional view of an example of a photovoltaic sensor 1 according to another embodiment of the invention. In this embodiment, the photovoltaic sensor 4 is disposed between the transparent electrode 3 and an anti-reflection layer 5. The photovoltaic sensor 1 of the second embodiment takes the structure of the substrate 2, the electrode 3 and the photovoltaic sensor 4 of the first embodiment in the same way. The anti-reflection layer 5 is advantageously made of the same material as the electrode 3. The anti-reflection layer 5 may have a thickness identical to that of the electrode 3, ±20%. Samples were notably taken with an anti-reflection layer 5 made of doped indium oxide with a thickness of 252 nm, or of ITZO with a thickness of 235 nm.

The surface 21 has an appropriate texturing that allows it to obtain an anti-reflective effect for a wide range of incidence angles. In particular, such an anti-reflection effect is much less sensitive to the angle of light incidence or wavelength of incident light than layer deposits with index gradients on a glass substrate. The texturing will be advantageously configured so that the optical reflection weighted by human spectral sensitivity at the surface 21 is less than 3%. Thus, the texturing of the surface 21 avoids glare or makes the sensor 1 slightly detectable. Optical reflection can be broken down into specular and diffuse optical reflection. Preferably, the texturing of the surface 21 is configured so that the proportion of diffuse reflection in the total optical reflection (weighted by human spectral sensitivity) is at least 45%. Thus, the surface 21 is even less detectable and further reduces the risk of glare. The human spectral sensitivity will correspond, for example, to a sensitivity model for photopic vision, for example the function V(A) defined by ISO.

The surface 22 has a suitable texturing that allows it to obtain an optical transmission effect to the transparent electrode 3, with a diffusion. Thus, by scattering the light transmitted in the electrode 3, the probability of absorption of an incident photon in the photovoltaic sensor 4 is increased in practice, and thus the conversion efficiency. This is particularly advantageous with a thin-film photovoltaic sensor 4. Advantageously, the texturing of the surface 22 is configured so that the proportion of diffuse transmission in the total optical transmission (weighted by human spectral sensitivity) is at least 45%.

Advantageously, the textures of the surfaces 21 and 22 are configured so that:
the optical reflection, weighted by human spectral sensitivity, of the surface 21 is lower than that of the surface 22;
the proportion of diffuse reflection in the total optical reflection (weighted by human spectral sensitivity) of the surface 22 is higher than that of the surface 21.

FIGS. 3 to 5 are scanning microscope views at the same scale of the surface of glass substrates that have been textured plasma etched with different parameters, according to procedures detailed below.

Such substrates have made it possible to carry out a number of experiments to determine their influence on the optical or electrical parameters of a photovoltaic sensor. The results of various experiments are illustrated in particular in the diagrams in FIGS. 6 to 14.

For the example shown in FIG. 3, the average pitch between the textured relief patterns is 300 nm. The height of the relief patterns is between 330 and 600 nanometres, with an estimated average of 465 nm. The ratio of height to pitch of the relief patterns is equal to 1.55.

For the example shown in FIG. 4, the average pitch between the relief patterns is 160 nm. The height of the relief patterns ranges from 170 to 340 nanometres, with an estimated average of 255 nm. The ratio of height to pitch of the relief patterns is equal to 1.59.

For the example shown in FIG. 5, the average pitch between the relief patterns is 80 nm. The height of the relief patterns is between 100 and 200 nanometres, with an estimated average of 150 nm. The ratio of height to pitch of the relief patterns is equal to 1.87.

For these three texturing examples, FIG. 6 illustrates the total transmission rate Tt, FIG. 7 illustrates the total reflection rate Rt, and FIG. 8 illustrates the ratio Dif between diffuse and total reflection. The dotted line curve corresponds to the example in FIG. 3, the dashed line curve corresponds to the example in FIG. 4 and the dash-dotted line curve corresponds to the example in FIG. 5. In each of the diagrams in FIGS. 6 to 8, the solid line curve corresponds to the human spectral sensitivity Sens, according to the function V(A) defined by ISO.

As shown in FIG. 6, texturing a glass surface according to the examples in FIGS. 3 to 5 provides a relatively high and fairly constant optical transmission, particularly in the optical spectrum.

Different optical parameters for the examples in FIGS. 3 to 5 are summarized in the following table:

TABLE 1

| Example: | FIG. 3 | FIG. 4 | FIG. 5 |
|---|---|---|---|
| Total RTP reflection in %, weighted | 2.16 | 1.23 | 1.59 |
| by sensitivity | | | |
| Minimum total reflection in %, over | 1.28 | 1.16 | 1.11 |
| the range 400-800 nm | | | |
| Wavelength in nm, for minimum total | 785 | 610 | 320 |
| reflection | | | |
| Diffuse RDP reflection in %, weighted | 1.84 | 0.66 | 0.35 |
| by sensitivity | | | |
| Percentage ratio between RDP and | 85.2 | 53.7 | 22 |
| RTP | | | |

The RTP reflection value on an outer surface of an untreated and untextured glass substrate is usually of the order of 8%. The RDP/RTP ratio for the same untreated and untextured glass substrate would usually be of the order of 1%.

The configuration of FIG. 4 will be advantageously used for the texturing of the surface 21. Indeed, the configuration obtained has the highest and most constant transmission on the visible spectrum, the lowest reflection level on the visible spectrum, and a relatively high RDP/RTP ratio. Such a configuration is therefore particularly appropriate for an anti-reflective property.

The configuration of FIG. 3 will be advantageously used for texturing the surface 22. Such a configuration is optimal for transmitting scattered light at the interface between the electrode 3 and the substrate 2. Thus, increasing the amount of light that the photovoltaic sensor 4 is likely to capture (as well as the conversion efficiency), which is particularly advantageous for a thin-film photovoltaic sensor 4.

The transparent electrode 3 must have a reduced resistance per square, typically less than 100 Ω/square, in order to optimally collect the electrical charges generated at the photovoltaic sensor 4. On the other hand, as shown in the diagram in FIG. 11, the thickness Ep of an electrode on a smooth glass substrate of the state of the art strongly affects the total optical reflection Rt. Therefore, a compromise must usually be found between a high thickness promoting low electrical resistance and a low thickness promoting low optical reflection. The solid line curve corresponds to the human spectral sensitivity Sens, according to the function V(A) defined by ISO.

In addition, the diagram in FIG. 9 compares the resistance per square of a transparent electrode in the case of deposition on a smooth glass substrate (diamond) and in the case of deposition on a textured glass substrate (square) corresponding to the example in FIG. 3, as a function of the thickness Ep of this electrode. In the case of the invention, there is an exponential decrease in resistance per square as a function of thickness, the decrease in resistance per square according to the state of the art being linear. There is also a much higher resistance per square with a textured glass substrate compared to a smooth substrate, for thin electrodes. There is also a much closer resistance per square between a textured glass substrate compared to a smooth substrate for thicker electrodes.

The diagram in FIG. 10 compares the electron mobility Mob of a transparent electrode in the case of deposition on a smooth glass substrate (diamond) and in the case of deposition on a textured glass substrate (square) corresponding to the example in FIG. 3, as a function of the thickness Ep of this electrode. The electron mobility for a glass substrate according to the invention is significantly reduced compared to that obtained for a smooth glass substrate.

However, since high electrode thickness values tend to increase optical reflection according to the teaching of FIG. 11 and tend to reduce electron mobility as according to the teaching of FIG. 12, it is a priori discouraged to use texturing according to invention, which would a priori involve either degrading the resistance per square with a low thickness or degrading the optical reflection with a high thickness.

The diagram in FIG. 12 illustrates the small influence of the electrode thickness Ep on the total optical reflection Rt for a textured glass substrate corresponding to the example in FIG. 3. Therefore, an electrode 3 for an optronic device 1 according to the invention may have a significant thickness to promote a reduced resistance per square, without increasing optical reflection. It can also be noted that the configuration of the texturing of the surface 22 of the substrate 2 is the main parameter for defining the total optical reflection at the interface 23.

The diagram in FIG. 13 illustrates the total optical reflection, weighted by human spectral sensitivity, as a function of the thickness of the electrode 3 formed on a textured glass substrate corresponding to the example in FIG. 3. An optimal thickness of 136 nm for the electrode 3 was calculated by simulation. Such a thickness allows a resistance per square of about 60 Ω/square for the electrode 3. In general, an electrode 3 with a thickness of at least 120 nm should be used, preferably at least 150 nm.

The diagram in FIG. 14 illustrates the diffuse optical reflection for different thicknesses Ep of the electrode 3 deposited on a textured substrate corresponding to the example in FIG. 3, as a function of wavelength. The solid line curve corresponds to the human spectral sensitivity Sens. A very small influence of the thickness of the electrode 3 on diffuse optical reflection is observed. In addition, the proportion of this diffuse optical reflection in relation to the total optical reflection was at least 40%, whereas this proportion is close to 0 for an electrode arranged on a smooth substrate. Therefore, the thickness of the electrode 3 does not affect the corresponding anti-glare or stealth properties. It can also be noted that the configuration of the texturing of the surface 22 of the substrate 2 is the main parameter for defining the proportion of diffuse optical reflection at the interface 23.

Advantageously, the surface 32 of the electrode 3 has an appropriate texturing, providing an optical transmission effect towards the photovoltaic sensor 4, with a diffusion. Thus, by scattering the light transmitted in the photovoltaic sensor 4, the probability of absorption of an incident photon in this photovoltaic sensor 4 is increased in practice, and thus the conversion efficiency. This is particularly advantageous with a thin-film photovoltaic sensor 4. Advantageously, the surface 32 is textured so that the proportion of diffuse transmission in the total optical transmission (weighted by human spectral sensitivity) is at least 45%.

Advantageously, the surface 32 is also textured so that the proportion of diffuse reflection in the total optical reflection (weighted by human spectral sensitivity) is at least 45%.

In addition, a texturing with deeper reliefs on the surface 22 retains a texturing on the interface between the deposited electrode 3 and the photovoltaic sensor 4. Indeed, for a deposition of a relatively thin electrode 3 (typically less than 1 μm), at least part of the relief on the surface 22 is retained on the interface 340. This optimizes the optical transmission between the electrode 3 and the photovoltaic sensor 4.

In addition, in order to maintain a texturing of the surface 32 by simply depositing the material of the electrode 3 on the surface 22, the thickness of the electrode 3 is advantageously at most equal to the depth of the texturing of the surface 22.

In addition, to promote the continuity of the electrode 3, it will have a thickness at least equal to 25% of the texturing depth of the surface 22.

Other comparative performance measurements were performed with four test samples:
a first sample with a glass substrate having smooth surfaces, a transparent conductive electrode made of AZO with a thickness of 269 nm, an optronic device comprising a hydrogenated amorphous silicon thin film, and an anti-reflection layer made of AZO with a thickness of 252 nm;
a second sample with a glass substrate having smooth surfaces, a transparent conductive electrode made of ITZO with a thickness of 254 nm, an optronic device comprising a hydrogenated amorphous silicon thin film, and an anti-reflection layer made of ITZO with a thickness of 235 nm;
a third sample with a glass substrate 2 having textured surfaces, an electrode 3 made of AZO with a thickness of 269 nm, a photovoltaic sensor 4 comprising a hydrogenated amorphous silicon thin film, and an anti-reflection layer 5 made of AZO with a thickness of 252 nm (exemplary structure according to the second embodiment);

a fourth sample with a glass substrate 2 having textured surfaces, an electrode 3 made of ITZO with a thickness of 254 nm, a photovoltaic sensor 4 comprising a hydrogenated amorphous silicon thin film, and an anti-reflection layer 5 made of ITZO with a thickness of 235 nm.

TABLE 2

| Example: | Voc (V) | Jsc (mA/cm²) | RdtC (%) | Rs (Ω/square) |
|---|---|---|---|---|
| Sample 1 | 0.91 | 7.9 | 4 | 21.7 |
| Sample 2 | 0.84 | 7.5 | 3.5 | 28.9 |
| Sample 3 | 0.87 | 11.1 | 4.9 | 43 |
| Sample 4 | 0.7 | 11.2 | 3.9 | 171.4 |

It can be seen that a certain number or electrical parameters are a priori poorer for samples corresponding to optronic devices according to the invention: a lower cell voltage Voc and a higher resistance per square Rs. However, it can be seen that the conversion efficiency RdtC and the current density Jsc generated by the photovoltaic sensors according to the invention are in practice improved. In practice, the degradation of electrical properties is very largely compensated by an improvement in optical properties (significant increase in the probability of capturing a photon in the optronic device in particular) in the optronic devices according to the invention.

The process for fabricating the optronic device can implement specific steps of texturing the surfaces 21 and 22 of the glass substrate 2.

In order to have a simple and inexpensive fabrication process, the texturing of the surfaces 21 and 22 of the glass substrate 2 is advantageously carried out without masking and with the same etching technology. Advantageously, the texturing of the surfaces 21 and 22 is carried out by dry etching of the vacuum plasma type. Such etching allows texturing to be carried out without passing the glass transition temperature of the glass. Advantageously, such etching is carried out for a maximum of 30 minutes.

Experimental results determined that etching parameters such as pressure, gas mixture type, polarization voltage and etching time made it possible to modify the roughness parameters of the etched surface. The roughness parameters of the etched surface can thus be modified, such as relief pitch, relief height, relief width and/or relief height/width ratio.

Experiments were thus carried out with the following plasma etching parameters on alumino-borosilicate glasses:
a CHF₃/O₂ gas mixture with a mixing ratio of between 10 and 15;
a working pressure of between 50 and 200 mTorr;
a radiofrequency power density of between 1.65 and 3.56 W/cm²;
an etching time of between 10 and 30 minutes.

In the example shown in FIG. 3, the etching parameters used are as follows:
a CHF₃/O₂ mixing ratio of 10;
a working pressure of 200 mTorr;
a power density of 3.56 W/cm²;
a treatment time of 30 minutes.

In the example shown in FIG. 4, the etching parameters used are as follows:
a CHF₃/O₂ mixing ratio of 12;
a working pressure of 100 mTorr;
a power density of 2.45 W/cm²;
a processing time of 20 minutes.

In the example shown in FIG. 5, the etching parameters used are as follows:
a CHF₃/O₂ mixing ratio of 15;
a working pressure of 50 mTorr;
a power density of 1.65 W/cm²;
a treatment time of 10 minutes.

The process for fabricating the optronic device 1 can implement specific steps to deposit the electrode 3 after the texturing of the surface 22. The electrode 3 can be formed, for example, by magnetron sputtering of a transparent conductive film onto the textured surface 22. The electrode material 3 can be known per se, for example a doped zinc oxide, a doped tin oxide, or a doped indium oxide.

Advantageously, the deposited electrode 3 must guarantee a resistance per square at most equal to 100 Ω/square. Such a resistance of the electrode 3 makes it possible to optimally collect the electrical charges generated at the photovoltaic sensor 4.

Advantageously, the deposited electrode 3 must have a minimum optical reflectivity over a wavelength range centred around 550 nm.

The process for fabricating the optronic device according to the invention can implement a known deposition step of a photovoltaic sensor 4 thin film. A known process for depositing hydrogenated amorphous silicon (a-Si:H) thin film on an electrode can thus be implemented.

1. An optronic device, comprising:
a glass substrate having opposed and textured first and second surfaces;
an electrically conductive material continuous and formed on the second surface of the glass substrate;
a photovoltaic sensor thin film formed on the electrically conductive material;
wherein
the texturing of the first surface of the glass substrate is configured to have a weighted optical reflection in the visible spectrum of less than 3%;
the texturing of the second surface of the glass substrate is configured to diffuse the light transmitted from the substrate to the transparent electrode.

2. The optronic device according to claim 1, wherein a contact interface between the photovoltaic sensor and the electrically conductive material is textured to diffuse light transmitted from the transparent electrode to the photovoltaic sensor.

3. The optronic device according to claim 1, wherein the texturing of the second surface is configured so that the proportion of diffuse transmission to the electrically conductive material, relative to the total optical transmission weighted by human spectral sensitivity, is at least 45%.

4. The optronic device according to claim 3, wherein the first surface of the glass substrate is textured so that the optical reflection of incident light weighted by the human spectral sensitivity on the first surface comprises at least 45% diffuse reflection.

5. The optronic device according to claim 1, wherein the optical reflection weighted by the human spectral sensitivity of the first surface is lower than that of the second surface.

6. The optronic device according to claim 1, wherein the proportion of diffuse reflection in the total optical reflection weighted by the human spectral sensitivity of the second surface is greater than that of the first surface.

7. The optronic device according to claim 1, wherein the electrically conductive material has a thickness of at least 120 nm.

8. The optronic device according to claim 1, wherein the electrically conductive material has a thickness at least equal to 25% of the texturing depth of said second surface.

9. The optronic device according to claim 1, wherein the electrically conductive material has a thickness at most equal to a depth of the texturing of said second surface.

10. The optronic device according to claim 1, wherein the electrically conductive material is made of a material selected from the group consisting of doped zinc oxide, doped tin oxide, doped indium oxide and their alloys.

11. The optronic device according to claim 1, wherein said photovoltaic sensor comprises a hydrogenated amorphous silicon (a-Si:H) thin film.

12. The optronic device according to claim 1, wherein said photovoltaic sensor is coated with an anti-reflection layer made of the same material as the electrically conductive material.

13. A process for fabricating an optronic device, comprising:
texturing a first surface by plasma etching of a glass substrate so that said first surface has an optical reflection weighted by human spectral sensitivity of less than 3%;
texturing a second surface by plasma etching of the glass substrate to obtain a texturing different from that of the first surface, so that said second surface diffuses the light transmitted through the substrate;
depositing a transparent conductive layer on the second surface of the substrate so as to form an electrically conductive material;
forming a photovoltaic sensor thin film on the electrically conductive material.

14. The process for fabricating an optronic device according to claim 13, wherein said texturing steps are performed without masking the surfaces of the glass substrate.

15. The process for fabricating an optronic device according to claim 13 or 11, wherein the thickness of the deposited transparent conductive layer is at least 120 nm.
